(19) United States
(12) Patent Application Publication
(10) Pub. No.: US 2026/0206660 A1
(43) Pub. Date: Jul. 16, 2026

(54) SEMICONDUCTOR ASSEMBLY COMPRISING AT LEAST ONE SEMICONDUCTOR ELEMENT

(71) Applicant: Siemens Aktiengesellschaft, München (DE)

(72) Inventors: Florian Schwarz, Fürth (DE); BENJAMIN SEWIOLO, Obermichelbach (DE)

(73) Assignee: Siemens Aktiengesellschaft, München (DE)

(21) Appl. No.: 19/134,019

(22) PCT Filed: Aug. 16, 2023
(86) PCT No.: PCT/EP2023/072565

§ 371 Date: May 29, 2025

(30) Foreign Application Priority Data
Nov. 30, 2022 (EP) 22210598.3
Feb. 7, 2023 (EP) 23155361.1

(51) Int. Cl. H10W 95/00; H10W 72/00; H10W 74/40; H10W 76/15

(52) U.S. Cl. CPC H10W 95/00; H10W 72/823; H10W 74/40; H10W 76/15

(57) ABSTRACT

A semiconductor arrangement, in particular a power semiconductor arrangement for a converter includes a housing, a semiconductor element arranged in the housing, and a potting compound capable of being melted by a heating process. The potting compound at least partially fills the housing and is in direct contact with the semiconductor element. A circuit carrier is arranged in the housing and connected to the semiconductor element by a force-fit.

The invention relates to a semiconductor arrangement, in particular a power semiconductor arrangement for a converter, with at least one semiconductor element.

The invention further relates to a converter with at least one such semiconductor arrangement.

Furthermore, the invention relates to a method for recycling or repairing a semiconductor arrangement with a semiconductor element.

Such semiconductor arrangements are used in a converter, for example. A “converter” is to be understood as a rectifier, an inverter, a transducer, or a direct current converter, for example. Such semiconductor arrangements usually comprise a housing, in which at least one semiconductor element is arranged. Such a semiconductor element may be a transistor, for example. A thermoset potting compound, in particular a silicone or epoxy potting compound, is commonly provided Inside the housing to protect the at least one semiconductor element.

Such semiconductor arrangements are used in a converter, for example. A “converter” is to be understood as a rectifier, an inverter, a transducer, or a direct current converter, for example. Such semiconductor arrangements usually comprise a housing, in which at least one semiconductor element is arranged. Such a semiconductor element may be a transistor, for example. A soft potting compound, in particular a silicone potting compound, is usually provided inside the housing to protect the at least one semiconductor element.

The published, unexamined patent application WO 2022/033745 A1 describes a power module with at least one power unit, which comprises at least one power semiconductor and a substrate, wherein the at least one power unit is at least partially surrounded by a housing. The housing is filled with a soft potting compound, in particular with a silicone potting compound.

Environmental and sustainability aspects are also becoming increasingly important in electronics development. In particular, improved recyclability is becoming the focus. Recyclability and repair costs are improved, for example, by eliminating the need for material-bonded connections, which can be produced by soldering, sintering, or welding.

The published, unexamined patent application EP 3 926 670 A1 describes a power semiconductor module with at least one power semiconductor element. In order to reduce the required installation space of the power semiconductor module and to increase its service life, it is proposed that the at least one power semiconductor element is in an electrically insulating and thermally conductive connection with a cooling element via a dielectric material layer, wherein the dielectric material layer rests flat on a surface of the cooling element and has a force-fit connection to the cooling element by means of a first force acting orthogonally to the surface of the cooling element.

The published, unexamined patent application WO 2018/046165 A1 describes a power module with a semiconductor component to be contacted on the top and bottom, wherein the semiconductor component can be electrically contacted on the top by a leadframe matrix using contact pressure.

A thermoset potting compound is very difficult to remove, for example, during recycling processes. Against this background, it is an object of the present invention to improve the recyclability of a semiconductor arrangement.

This object is achieved according to the invention by a semiconductor arrangement, in particular a power semiconductor arrangement for a converter, with at least one semiconductor element, wherein the semiconductor element is arranged in a housing, wherein the housing is at least partially filled with a potting compound, which can be melted via a heating process and is in direct contact with the semiconductor element.

Furthermore, the object is achieved according to the Invention by a power converter with at least one such semiconductor arrangement.

Moreover, the object is achieved according to the Invention by a method for recycling or repairing a semiconductor arrangement with a semiconductor element, wherein the semiconductor element is arranged in a housing, wherein the housing is at least partially filled with a potting compound, which can be melted via a heating process and is in direct contact with the semiconductor element, comprising the following steps: liquefy the potting compound by heating, discharge the liquefied potting compound from the housing, and remove the semiconductor element from the housing.

Moreover, the object is achieved according to the invention by a method for recycling or repairing a semiconductor arrangement with a semiconductor element, wherein the semiconductor element is arranged in a housing, wherein the housing is at least partially filled with a potting compound, which can be melted via a heating process and is in direct contact with the semiconductor element, comprising the following steps: vaporize the potting compound by heating, discharge the gaseous potting compound from the housing, and remove the semiconductor element from the housing.

The advantages and preferred embodiments listed below with respect to the semiconductor arrangement can be transferred analogously to the converter, the production method, and the use.

The invention is based on the idea of improving the recyclability of a semiconductor arrangement by replacing a commonly used soft potting compound made from a thermoset with a potting compound that can be melted via a heating process. A housing of the semiconductor arrangement, in which at least one semiconductor element is arranged, is at least partially filled with the meltable potting compound in such a way that the semiconductor element is in direct contact with the meltable potting compound. In particular, the semiconductor element is at least partially surrounded by the meltable potting compound. The meltable potting compound is electrically insulating and can, for example, contain a thermoplastic or paraffin. In particular, the meltable potting compound has a dielectric strength of 2 kV/mm at room temperature. High-melting paraffins or other waxes, in particular with a melting point above 100° C., are potential options. The potting compound can be removed in the liquefied or gaseous state. The potting compound is heated, for example, by an electric heating device, in particular by means of a hotplate, by a metal base plate, or a heat sink. In contrast to commonly used thermosets, the meltable potting compound can be removed far more easily and essentially without trace. Simple disassembly for repair or recycling is facilitated by such a meltable potting compound.

Another embodiment variant provides for a circuit carrier to be arranged in the housing, wherein the semiconductor element has a force-fit connection to the circuit carrier, in particular by means of at least one pressure contact. The circuit carrier can be embodied as a substrate, for example, in particular a direct copper bonded (DCB) substrate. Such a pressure contact can be embodied as a busbar, for example. Alternatively, a spring, a screw, and/or a bracket can be used for a force-fit connection of the semiconductor element. Such a force-fit connection of the semiconductor element is detachable and easy to remove essentially without trace when disassembling for repair or recycling, particularly in combination with the filling of the meltable potting compound.

Another embodiment variant provides for the housing to have a discharge opening for removal of the meltable potting compound. The discharge opening is arranged, for example, in a housing frame or in a housing cover and facilitates a discharge of the liquefied or gaseous potting compound. In particular, the discharge opening can also be used to fill the housing with the meltable potting compound. The discharge opening can also be embodied as a predetermined breaking point or markings for the insertion of an opening in the housing. In particular, the discharge opening facilitates a discharge without removing the cover, wherein the cover enables more homogeneous heating of the potting compound, so that it is also easier to remove the potting compound essentially without trace.

Another embodiment variant provides for the discharge opening to be closed in a fluid-tight and detachable manner with a first closing element during operation of the semiconductor arrangement. The first closing element is embodied, for example, as a sealing plug. Such a sealing plug facilitates easy removal of the potting compound and reliably and cost-effectively guarantees the tightness of the housing.

Another embodiment variant provides for the housing to have a pressure compensation opening, which is closed in a fluid-tight and detachable manner with a second closing element during operation of the semiconductor arrangement. The pressure compensation opening can also be embodied as a predetermined breaking point or markings for the insertion of an opening in the housing. The second closing element is embodied, for example, as a sealing plug. In particular, the discharge opening and the pressure compensation opening are arranged so that at least 60% of the enclosed volume can be between the openings. An airflow through the pressure compensation opening compensates pressure in the housing, so that the potting compound can be removed from the housing essentially without trace.

Another embodiment variant provides for the housing to be at least partially made from a meltable material, which has a higher melting temperature than the meltable potting compound. This ensures that the housing does not liquefy when the potting compound is heated and discharged.

Another embodiment variant provides for the semiconductor arrangement to comprise an electric heating device, which is at least partially arranged within the housing. For example, a heating conductor is arranged in the area of an inner surface of a housing frame or of a housing cover. Such a heating device, particularly in contrast to heating with a heat sink or a base plate, reduces the required energy input and prevents unintended detaching of components within the housing.

Another embodiment variant provides for the electric heating device to comprise a heating coil, which is at least partially connected to the housing, The heating coil can be connected to an inner surface of a housing frame or of a housing cover. The heating coll can be energized without contact via a transformer, for example. Such a heating device facilitates easy and rapid heating of the potting compound.

The invention is described in more detail and explained below using the exemplary embodiments presented in the figures.

It is shown in:

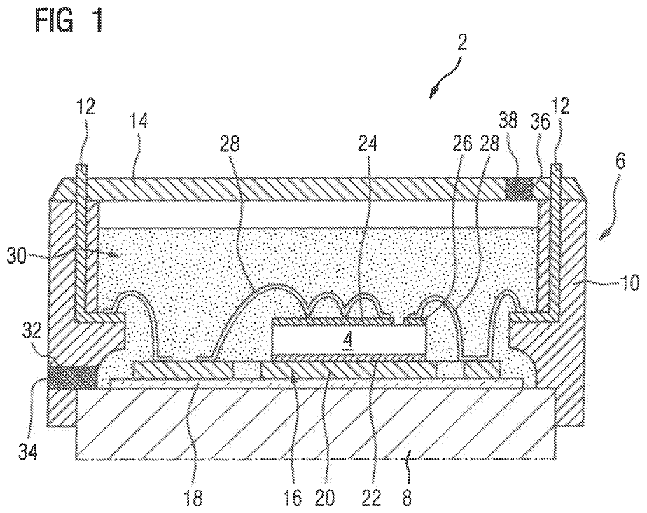

FIG. 1 a schematic sectional representation of a first embodiment variant of a semiconductor arrangement,

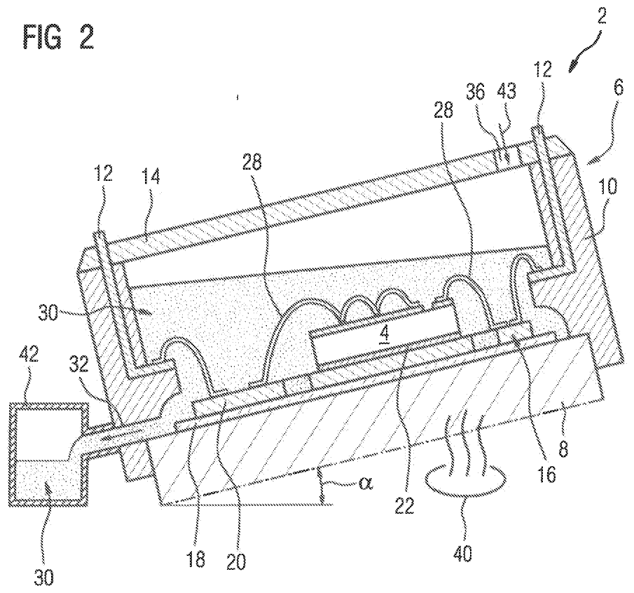

FIG. 2 a recycling of a first embodiment variant of a semiconductor arrangement in a schematic sectional representation,

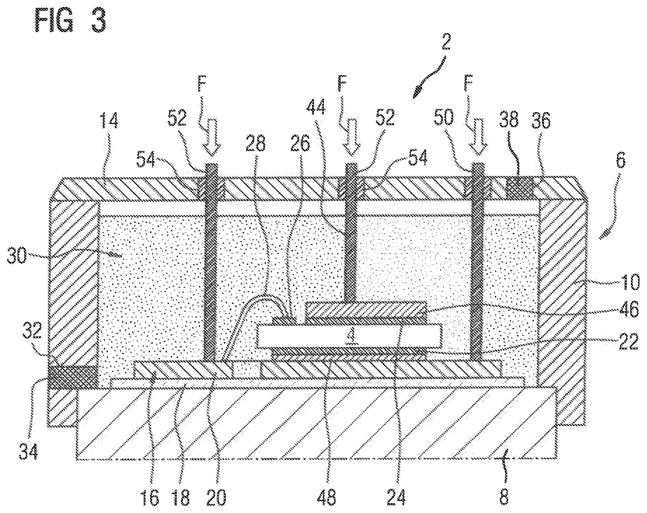

FIG. 3 a schematic sectional representation of a second embodiment variant of a semiconductor arrangement,

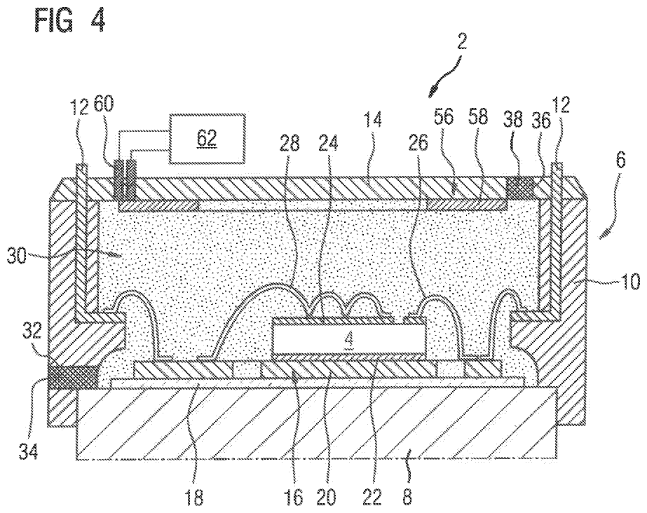

FIG. 4 a schematic sectional representation of a third embodiment variant of a semiconductor arrangement,

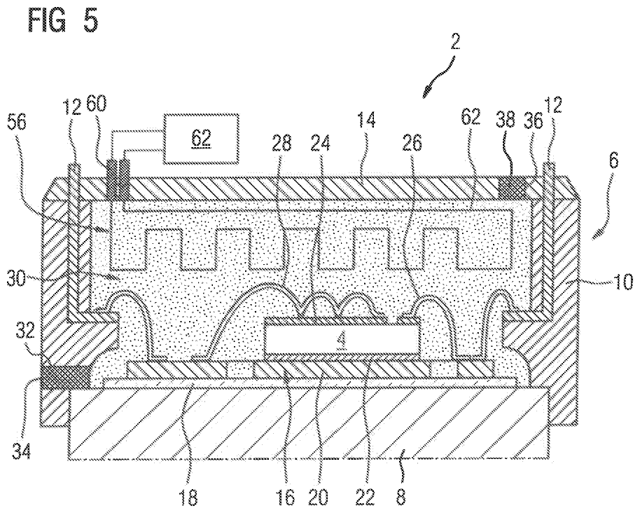

FIG. 5 a schematic sectional representation of a fourth embodiment variant of a semiconductor arrangement,

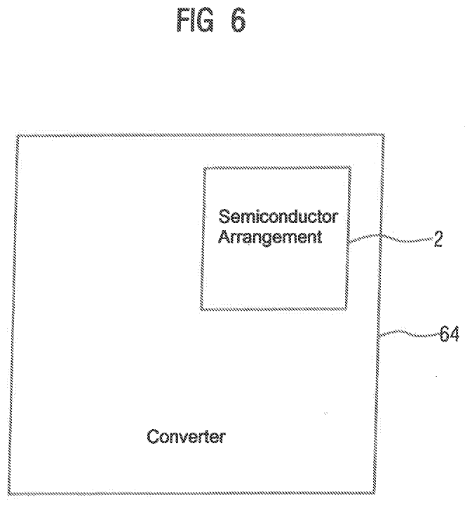

FIG. 6 a schematic representation of a converter.

The exemplary embodiments explained below are preferred embodiment variants of the invention. In the exemplary embodiments, the described components of the embodiment variants each represent individual features of the invention that are to be considered independently of each other, which also each develop the invention independently of each other and thus should be viewed as part of the invention, both individually or in a combination other than that shown. Moreover, the described embodiment variants can also be supplemented with the other features of the invention that have already been described.

The same reference characters have the same meaning in the various figures.

FIG. 1 shows a schematic sectional representation of a first embodiment variant of a semiconductor arrangement 2 with a semiconductor element 4, which is arranged in a closed housing 6. For example, the semiconductor element 4 is embodied as a vertical transistor, in particular as an IGBT or vertical SIC MOSFET. The housing 6 comprises a metal heat sink 8, a housing frame 10 with multiple pins 12 and a housing cover 14. The housing frame 10 and the housing cover 14 are made from a plastic, for example, wherein the pins 12 are molded or pressed into the housing frame 10. The heat sink 8, which acts as a base plate, is made from copper, aluminum, or one of their alloys, for example. A circuit carrier 16 is connected flat to the heat sink 8. For example, the circuit carrier 16 comprises a dielectric material layer 18, which contains in particular aluminum oxide, aluminum nitride, or an organic electrically insulating and thermally conductive material, and metallization 20, which contains copper, gold, molybdenum, silver, or one of their alloys, for example. The dielectric material layer 18 can be connected to the heat sink by means of pressing or an adhesive bond. Alternatively, the circuit carrier 16 can be embodied as a substrate, in particular a direct copper bonded (DCB) substrate, which is soldered to the heat sink 8, for example.

The semiconductor element 4 has a first power contact 22, in particular a collector contact, and a second power contact 24 on an opposite side, in particular an emitter contact, and a control contact 26, in particular a gate contact. The first power contact 22 of the semiconductor element 4 has, for example, a material-bonded connection to the metallization 20 of the circuit carrier 16. The material-bonded connection of the semiconductor element 4 and the circuit carrier 16 can be achieved by soldering and/or sintering, for example. The second power contact 24 and control contact 26 arranged on a side of the semiconductor element 4 facing away from the circuit carrier 16 are each connected to the metallization 20 of the circuit carrier 16 by wiring means 28, wherein the metallization 20 is wired to the pins 12 of the housing 6. In this manner, the contacts 22, 24, 26 of the semiconductor element 4 are led out of the housing 6 and can be contacted electroconductively from outside by means of the pins 12. The wiring means 28 is embodied, for example, as bonding wires or bonding ribbons, which are welded in particular by means of ultrasonic wire bonding.

The housing 6 is filled with a potting compound 30, which can be melted via a heating process and is in direct contact with the semiconductor element 4, and partially surrounds this. The potting compound 30 can contain a thermoplastic or paraffin, for example. In particular, high-melting paraffins or other waxes with a melting point above 100° C. are potential options, so that the potting compound is solid at room temperature. The potting compound 30 can contain fillers such as ceramic particles. The potting compound 30 can be liquefied or vaporized for removal.

The housing 6 can be at least partially made from a meltable material, which has a higher melting temperature than the meltable potting compound 30, in order to prevent the housing also liquefying when the meltable potting compound 30 is heated. The housing has a discharge opening 32 for removal of the meltable potting compound 30, which is closed in a fluid-tight and detachable manner with a first closing element 34 during operation of the semiconductor arrangement 2. The first closing element 34 is embodied, for example, as a sealing plug. Furthermore, the housing 6 has a pressure compensation opening 36, which is closed in a fluid-tight and detachable manner with a second closing element 38 during operation of the semiconductor arrangement 2. The openings 32, 36 are arranged so that at least 60% of the enclosed volume can be between the openings 32, 36. The opening 32, 36 can also be embodied as predetermined breaking points or markings for the insertion of an opening in the housing 6.

FIG. 2 shows a recycling of a first embodiment variant of a semiconductor arrangement 2 in a schematic sectional representation, wherein the liquefied potting compound 30 is discharged via the discharge opening 32. For this purpose, the first closing element 34 is removed from the discharge opening 32 and the second closing element 38 from the pressure compensation opening 36. The semiconductor arrangement 2 is embodied as represented in FIG. 1. The potting compound 30 is liquefied by heating with an electric heating device, for example, by means of a hotplate. Alternatively, heating can be used to transform the potting compound 30 into the gaseous state for removal.

The liquefied potting compound 30 is discharged via the discharge opening 32 into a collecting container 42. For example, the housing 6 is tilted by an angle a. The angle a can be in the range from 10° to 90° and be varied during discharge, in particular can be varied multiple times. Additionally or alternatively, the collecting container 42 can comprise a suction device for suctioning the potting compound 30. Separate collection of the potting compound 30 improves environmental compatibility or sustainability. An airflow 43 through the pressure compensation opening 36 compensates pressure in the housing 6, so that the potting compound 30 can be removed from the housing 6, in particular without trace. Alternatively, in the case of wire-bonded circuits pressure compensation can also be effected without a pressure compensation opening 36 by removing the housing cover 14, wherein the housing cover 14 enables more homogeneous heating of the potting compound 30.

In a subsequent step, the housing cover 14 is opened and the semiconductor element 4 is removed. Furthermore, the circuit carrier 16, in particular the DCB substrate, can be removed. This separates the components cleanly for further use.

The liquefied potting compound 30 can alternatively be discharged via the discharge opening 32 for repair, wherein the housing cover 14 is opened for removal of at least one defective semiconductor element 4. In a subsequent step, at least the defective semiconductor element 4 is replaced. In particular, the circuit carrier 16 can be removed with at least one defective semiconductor element 4, wherein the removed components are replaced in a subsequent step.

FIG. 3 shows a schematic sectional representation of a second embodiment variant of a semiconductor arrangement 2, wherein the semiconductor element 4 has a force-fit connection to the circuit carrier 16 by means of a first pressure contact 44. In addition to the mechanical fixing, the first pressure contact 44 also produces the electrical contacting of the second power contact 24 of the semiconductor element 4.

A first metal contacting element 46 is connected to the second power contact 24 of the semiconductor element 4 and acts as a buffer layer, which distributes a force F from the pressure contact 44, preventing the occurrence of pressure peaks in the sensitive semiconductor element 4. The first metal contacting element 46 can be embodied, for example, as a small metal plate, which contains copper and/or molybdenum and has a thickness in the range from 25 um to 250 um. The first metal contacting element 46 can be connected to the semiconductor element 4 through material bonding, for example, through soldering or sintering. Alternatively, the first metal contacting element 46 can be sprayed on by means of a thermal spraying process, in particular in the form of copper and/or molybdenum particles. An optional second metal contacting element 48, which can, for example, be embodied as a small metal plate containing copper and/or molybdenum, is arranged between the first power contact 22 and the circuit carrier 16.

A second pressure contact 50 and a third pressure contact 52 have a force-fit connection to the metallization 20 of the circuit carrier 16 for electrical contacting of the first power contact 22 or of the control contact 26, wherein the control contact 26 is connected to the metallization 20 via at least one wiring means 28. The circuit carrier 16 is pressed against the heat sink 8 via the pressure contacts 44, 50, 52 and thus has a force-fit connection to this.

The pressure contacts 44, 50, 52 are embodied as busbars. For example, the busbars are made from copper or a copper alloy. Additionally or alternatively, the pressure contacts 44, 50, 52 can have a spring, a screw, or a bracket. The busbars are led out of the housing 6 via sealing elements 54, so that the housing 6 has a fluid-tight seal. A plurality of first pressure contacts 44 arranged in particular equidistantly in a square or rectangle on the metal contacting element 46 (for example, 2×2, 2×3, 3×3, 3×4, or 4×4), leads to improved mechanical fixing of the semiconductor element 4, more homogeneous pressure distribution, and low-resistance electrical contacting. The further embodiment of the semiconductor arrangement 2 in FIG. 3 corresponds to the embodiment in FIG. 1. Recycling is effected as shown in FIG. 2, wherein after the potting compound 30 has been discharged, the force-fit connections of the pressure contacts 44, 50, 52 are detached, and the semiconductor element 4 now resting loosely on the circuit carrier 16 can easily be removed for further use without causing damage. The circuit carrier 16 now resting loosely on the heat sink 8 can also easily be removed for further use without causing damage.

FIG. 4 shows a schematic sectional representation of a third embodiment variant of a semiconductor arrangement 2, wherein an electrical heating device 56 is arranged in the housing 6. The electrical heating device 56 has a heating coll 58, which is connected to the housing cover 14, for example. The heating coil 58 is made together with the plastic housing cover 14 by means of a molded interconnect device (MID) process. The heating device can comprise electrical contacts 60 for connecting to a power source 62, wherein the electrical contacts 60 are arranged running through the housing cover 14. Alternatively, the heating coll 58 can be energized without contact via a transformer. The further embodiment of the semiconductor arrangement 2 in FIG. 4 corresponds to the embodiment in FIG. 1. The contacting of the semiconductor element 4 can be effected by means of pressure contacts 44, 50, 52, as shown in FIG. 3.

FIG. 5 shows a schematic sectional representation of a fourth embodiment variant of a semiconductor arrangement 2, wherein the electrical heating device 56 comprises at least one electrically insulating heating wire 62, which is arranged running through the housing 6. The at least one electrically insulating heating wire 62 is potted with the potting compound 30 and can directly heat this. The further embodiment of the semiconductor arrangement 2 in FIG. 5 corresponds to the embodiment in FIG. 4.

FIG. 6 shows a schematic representation of a converter 64, which comprises a semiconductor arrangement 2. The converter 64 can comprise more than one semiconductor arrangement 2.

The invention can be summarized as a semiconductor arrangement 2, in particular a power semiconductor arrangement for a converter 64, with at least one semiconductor element 4. In order to Improve the recyclability of a semiconductor arrangement 2, it is proposed that the semiconductor element 4 is arranged in a housing 6, wherein the housing 6 is at least partially filled with a potting compound 30, which can be melted via a heating process and is in direct contact with the semiconductor element 4.

1.-15. (canceled)

16. A semiconductor arrangement, in particular a power semiconductor arrangement for a converter, the semiconductor arrangement comprising:
a housing;
a semiconductor element arranged in the housing;
a potting compound capable of being melted by a heating process, the potting compound at least partially filling the housing and directly contacting the semiconductor element; and
a circuit carrier arranged in the housing and connected to the semiconductor element by a force-fit.

17. The semiconductor arrangement of claim 16, further comprising a pressure contact by which the semiconductor element is connected to the circuit carrier by the force-fit.

18. The semiconductor arrangement of claim 16, wherein the housing is at least partially made from a meltable material having a melting temperature which is higher than a melting temperature of the potting compound.

19. A semiconductor arrangement, in particular a power semiconductor arrangement for a converter, the semiconductor arrangement comprising:
a housing;
a semiconductor element arranged in the housing; and
a potting compound capable of being melted by a heating process, the potting compound at least partially filling the housing and directly contacting the semiconductor element.
wherein the housing comprises a discharge opening for removal of the potting compound.

20. The semiconductor arrangement of claim 19, further comprising a first closing element designed to close the discharge opening in a fluid-tight and detachable manner during operation of the semiconductor arrangement.

21. The semiconductor arrangement of claim 19, wherein the housing comprises a pressure compensation opening, the semiconductor arrangement further comprising a second closing element designed to close the pressure compensation opening in a fluid-tight and detachable manner during operation of the semiconductor arrangement.

22. The semiconductor arrangement of claim 19, wherein the housing is at least partially made from a meltable material having a melting temperature which is higher than a melting temperature of the potting compound.

23. A semiconductor arrangement, in particular a power semiconductor arrangement for a converter, the semiconductor arrangement comprising:
a housing;
a semiconductor element arranged in the housing;
a potting compound capable of being melted by a heating process, the potting compound at least partially filling the housing and directly contacting the semiconductor element; and
an electrical heating device at least partially arranged within the housing.

24. The semiconductor arrangement of claim 23, wherein the electrical heating device comprises a heating coil, which is at least partially connected to the housing.

25. A converter, comprising the semiconductor arrangement of claim 16.

26. The converter of claim 25, wherein the semiconductor arrangement comprises a pressure contact by which the semiconductor element is connected to the circuit carrier by the force-fit.

27. The converter of claim 25, wherein the housing is at least partially made from a meltable material having a melting temperature which is higher than a melting temperature of the potting compound.

28. A converter, comprising the semiconductor arrangement of claim 19.

29. A converter, comprising the semiconductor arrangement of claim 23,

30. A method for recycling or repairing a semiconductor arrangement with a semiconductor element arranged in a housing which is at least partially filled with a meltable potting compound that is in direct contact with the semiconductor element, the method comprising:
liquefying the potting compound by a heating process;
discharging the liquefied potting compound from the housing; and
removing the semiconductor element from the housing.

31. The method of claim 30, further comprising:
arranging a circuit carrier in the housing,
connecting the semiconductor element to the circuit carrier by a force-fit via a pressure contact; and
detaching the pressure contact when removing the semiconductor element from the housing.

32. The method of claim 30, further comprising:
forming a discharge opening in the housing for removal of the potting compound;
closing the discharge opening in a fluid-tight and detachable manner with a first closing element during operation of the semiconductor arrangement;
removing the first closing element to open the discharge opening before the liquefied potting compound is discharged; and
discharging the liquefied potting compound via the discharge opening.

33. The method of claim 32, further comprising:
forming a pressure compensation opening in the housing;
closing the pressure compensation opening in a fluid-tight and detachable manner with a second closing element during operation of the semiconductor arrangement;
removing the second closing element to open the pressure compensation opening before the liquefied potting compound is discharged; and
compensating a pressure via the pressure compensation opening when the liquefied potting compound is discharged via the discharge opening.

34. The method of claim 30, further comprising:
at least partially arranging an electrical heating device within the housing; and
at partially effecting the heating process via the electrical heating device.

35. A method for recycling or repairing a semiconductor arrangement with a semiconductor element arranged in a housing which is at least partially filled with a meltable potting compound that is in direct contact with the semiconductor element, the method comprising:
vaporizing the potting compound by a heating process;
discharging the gaseous potting compound from the housing; and
removing the semiconductor element from the housing.
